(19) United States
(12) Patent Application Publication
(10) Pub. No.: US 2026/0344337 A1
(43) Pub. Date: Oct. 29, 2026

(54) SEMICONDUCTOR CONTINUOUS PROCESSING INTEGRATED SYSTEM

(71) Applicant: KENMEC MECHANICAL ENGINEERING CO., LTD., Taipei City (TW)

(72) Inventors: CHIH-CHUN KO, Taipei City (TW); CHIA-CHU TSENG, Taipei City (TW)

(21) Appl. No.: 19/653,989

(22) Filed: Apr. 21, 2026

(30) Foreign Application Priority Data
Apr. 23, 2025 (TW) 114115255

(51) Int. Cl. H10P 72/00; H10P 72/30

(52) U.S. Cl. CPC H10P 72/0454; H10P 72/0464; H10P 72/3302

(57) ABSTRACT

A semiconductor continuous processing integrated system for moving semiconductor objects, which includes an equipment front end module (EFEM), a central transfer module, and a storage and sorting apparatus. One side of the EFEM is provided with a load port to input or output process object devices (PODs) for carrying the semiconductor objects. The central transfer module is disposed at another side of the EFEM and includes a plurality of transfer units. The semiconductor processing apparatuses are respectively disposed at two sides of the central transfer module. Each transfer unit has a robotic arm and a temporary storage area. The temporary storage area is used to temporarily store various PODs. The robotic arm is used to pick and place the semiconductor objects. The storage and sorting apparatus is disposed at another side of the EFEM and is used to store PODs to increase storage capacity of the semiconductor objects.

### CROSS-REFERENCE TO RELATED PATENT APPLICATION

This application claims the benefit of priority to Taiwan Patent Application No. 114115255, filed on Apr. 23, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor continuous processing integrated system, and more particularly to a processing integrated system capable of transferring semiconductor objects to various semiconductor processing apparatuses.

### BACKGROUND OF THE DISCLOSURE

In recent years, third-generation semiconductors SiC and GaN have attracted attention from industry and the public media. Their main applications lie in power semiconductor devices. Due to the demand for energy saving and carbon reduction, emerging energy industries such as electric vehicles, solar power generation, DC grids, and charging stations require high conversion efficiency power semiconductors.

Semiconductor processes are mainly divided into front-end processes and back-end processes. The front-end processes include wafer manufacturing such as crystal growth, slicing, grinding, polishing, cleaning, photolithography, etching, thin film deposition, and ion implantation. The back-end processes include packaging, testing, and packing. In semiconductor processing, appropriate transport mechanisms are required to transport semiconductor objects (such as wafers or ingots) to various processing equipment. However, in existing semiconductor processes, poor transport routing is often encountered. Each process must be carried out sequentially by individual equipment, resulting in low automation efficiency and large footprint, making it difficult to improve production efficiency.

### SUMMARY OF THE DISCLOSURE

In response to the above-referenced technical inadequacy, the present disclosure provides a semiconductor continuous processing integrated system, which is primarily configured to address issues of inefficient object transfer paths and difficulty in improving production efficiency in semiconductor manufacturing processes. The system enables transfer of semiconductor objects to various semiconductor processing apparatuses, thereby facilitating automated production and improving production efficiency.

One of the technical aspects adopted by the present disclosure is to provide a semiconductor continuous processing integrated system including an equipment front end module, a central transfer module, and at least one storage and sorting apparatus. The equipment front end module is provided with a load port, and the load port is configured to load and unload a plurality of carriers that are configured for carrying a plurality of semiconductor objects. The central transfer module is disposed at one side of the equipment front end module, the central transfer module and the load port are located at two opposite sides of the equipment front end module, the equipment front end module and the central transfer module are arranged in a straight line, a plurality of semiconductor processing apparatuses are disposed at two opposite sides of the central transfer module, a first transport path is defined along the equipment front end module and the central transfer module, the semiconductor objects are configured to move along the first transport path between the equipment front end module and the semiconductor processing apparatus, the central transfer module includes a plurality of transfer units arranged along the first transport path, each of the transfer units includes a robotic arm and a temporary storage area for temporarily storing the carriers, and the robotic arm is configured to pick and place the semiconductor objects. The at least one storage and sorting apparatus is disposed at another side of the equipment front end module, the equipment front end module and the storage and sorting apparatus are arranged in a straight line, a second transport path is defined along the equipment front end module and the storage and sorting apparatus, the semiconductor objects are configured to move along the second transport path between the equipment front end module and the storage and sorting apparatus, and the storage and sorting apparatus includes a plurality of storage slots arranged in a plurality of layers, and the storage slots of each of the layers are configured for storing the carriers.

The beneficial effects of the present disclosure are that the semiconductor continuous processing integrated system includes an equipment front end module, a central transfer module, and at least one storage and sorting apparatus. The equipment front end module, the central transfer module, and the storage and sorting apparatus of the present disclosure can be arranged in an optimized configuration, such that the semiconductor objects can be transferred from the equipment front end module to the semiconductor processing apparatus, or from the semiconductor processing apparatus to the equipment front end module. Accordingly, bidirectional transport of the semiconductor objects is achieved, thereby forming an optimized object transfer path, which facilitates automated production and improves production efficiency.

Furthermore, the central transfer module of the present disclosure includes a plurality of transfer units. The transfer units are configured in a modular design, allowing flexible assembly and expansion in response to process requirements, thereby quickly realizing the construction of the central transfer module.

Additionally, the storage and sorting apparatus is disposed at a side of the equipment front end module for storing and sorting the carriers and the semiconductor objects, thereby increasing the storage capacity of “the semiconductor objects pending processing (or awaiting processing)” and “the semiconductor objects that have completed processing (or undergone processing),” and significantly improving production efficiency.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a semiconductor continuous processing integrated system according to one embodiment of the present disclosure;

FIG. 2 is a front schematic view of the semiconductor continuous processing integrated system according to one embodiment of the present disclosure;

FIG. 3 is a top schematic view of the semiconductor continuous processing integrated system according to one embodiment of the present disclosure; and

FIG. 4 is a side schematic view of the semiconductor continuous processing integrated system according to one embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. It should be noted that the examples provided in the following description are merely illustrative embodiments and are not intended to limit the scope of the present disclosure.

### Embodiments

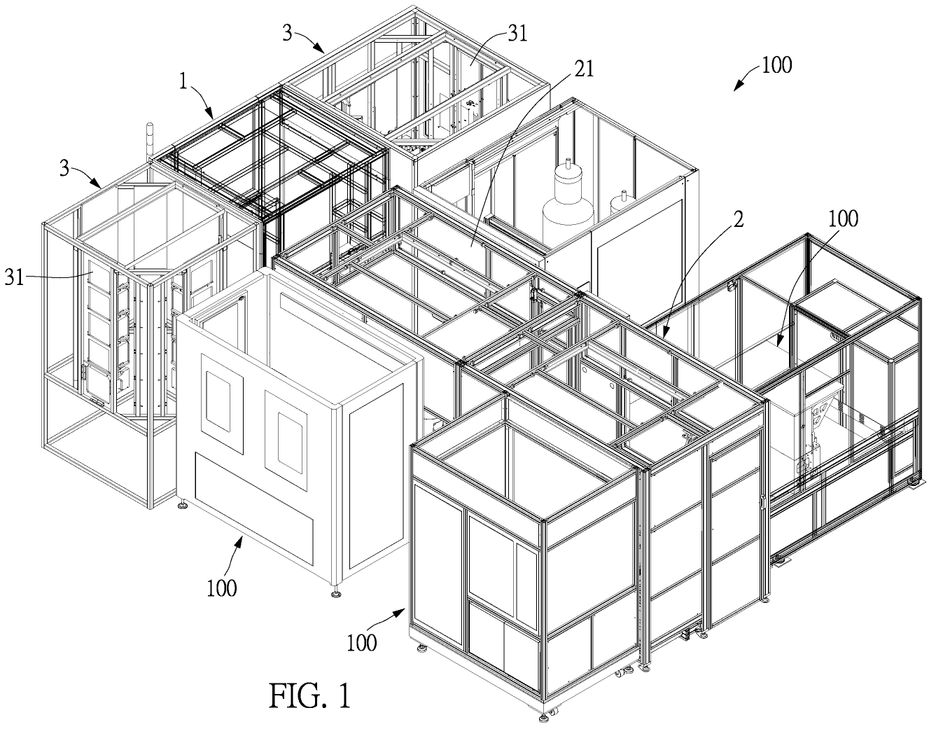

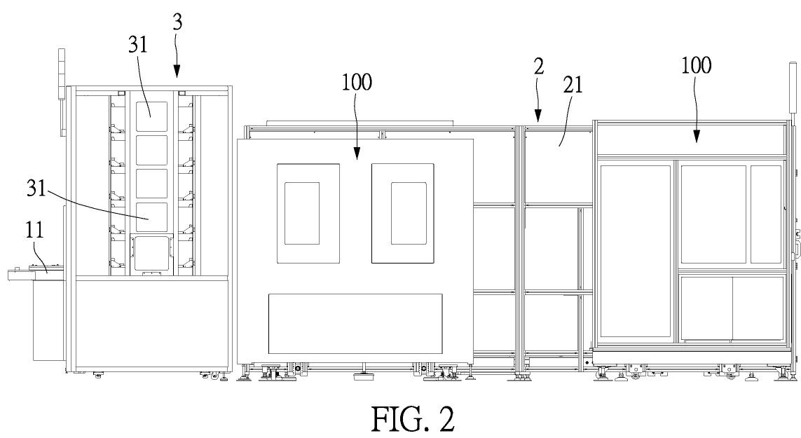

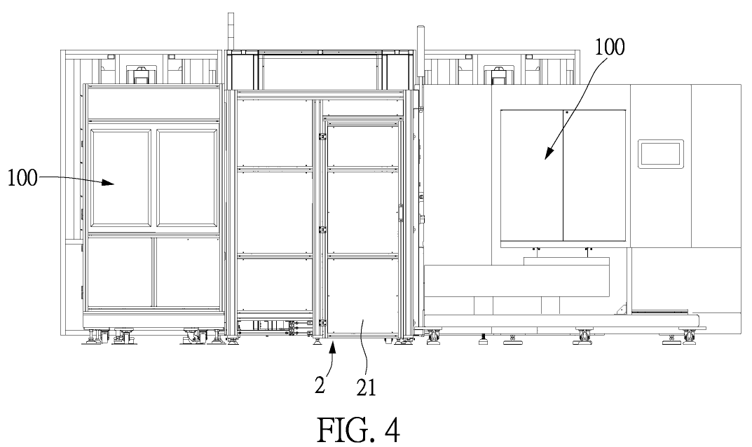

Referring to FIGS. 1-4, the present disclosure provides a semiconductor continuous processing integrated system for transferring semiconductor objects. The semiconductor objects may be compound semiconductors, such as third-generation semiconductors. The semiconductor continuous processing integrated system of the present disclosure is preferably applied to front-end processes of compound semiconductors, but is not limited thereto. The semiconductor continuous processing integrated system includes an equipment front end module (EFEM) 1, a central transfer module 2, and at least one storage and sorting apparatus 3 (or sorter).

The equipment front end module 1 is a front-end transport device, which may be an interface system compatible with SEMI standards, and may cooperate with a transport device (such as overhead transport) to convey semiconductor objects. The equipment front end module 1 is provided with a load port 11 to load and unload (input and output) carriers such as PODs (Process Object Devices), and the carriers can be configured to carry semiconductor objects (such as wafers or crystal ingots). The equipment front end module 1 may be provided with one or more load ports 11, and the quantity is not limited. Transport mechanisms such as robotic arms may be provided within the equipment front end module 1. The present disclosure does not limit the structure of the equipment front end module 1, and the detailed description of the equipment front end module 1 is omitted.

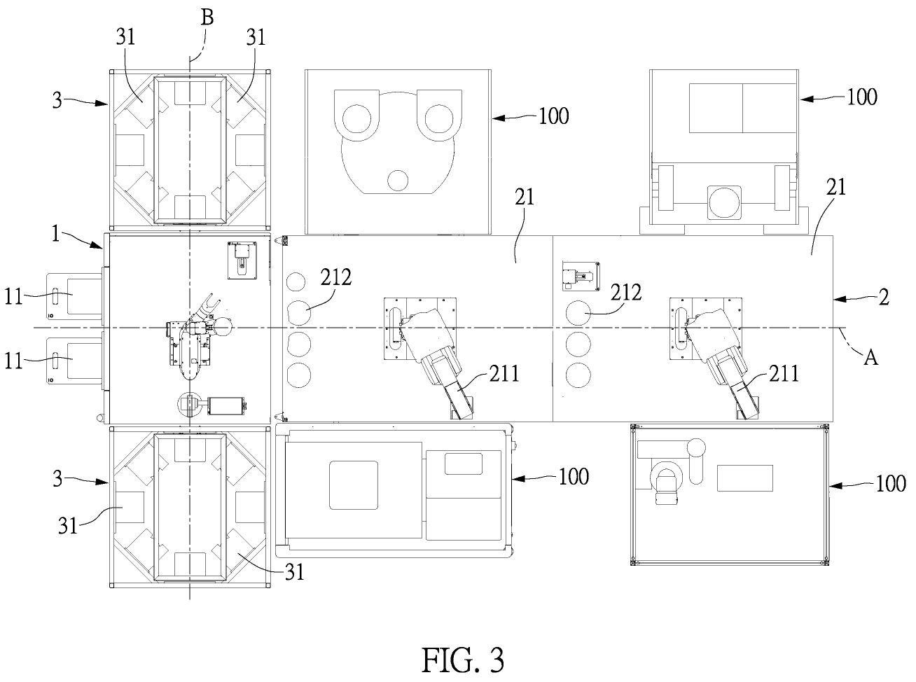

The central transfer module 2 is disposed at another side of the equipment front end module 1, and the central transfer module 2 is disposed at a side of the equipment front end module 1 away from the load port 11, such that the central transfer module 2 and the load port 11 are respectively located at two opposite sides of the equipment front end module 1. The equipment front end module 1 and the central transfer module 2 are arranged in a straight line. A plurality of semiconductor processing apparatuses 100 are respectively disposed at two opposite sides of the central transfer module 2. A first transport path A (as shown in FIG. 3) is defined along the equipment front end module 1 and the central transfer module 2, and the first transport path A is located along a straight line. The semiconductor objects can move along the first transport path A between the equipment front end module 1 and the semiconductor processing apparatuses 100, allowing the semiconductor objects to be rapidly transferred from the equipment front end module 1 along the first transport path A. The semiconductor objects can be transferred along the first transport path A to each of the semiconductor processing apparatuses 100, and the semiconductor objects can also be transferred from each of the semiconductor processing apparatuses 100 to the equipment front end module 1 along the first transport path A.

The central transfer module 2 includes a plurality of transfer units 21, and the transfer units 21 are arranged along the first transport path A. The transfer units 21 can be formed as a modular design that can be flexibly assembled and expanded according to process requirements, and the quantity of the transfer units 21 is not limited. The transfer units 21 are connected with each other, allowing for smooth conveyance of the semiconductor objects. In this embodiment, two transfer units 21 are provided; in other embodiments, three, four, five, or more transfer units 21 may be provided. The plurality of semiconductor processing apparatuses 100 are respectively disposed at two sides of the central transfer module 2, and the semiconductor processing apparatuses 100 are respectively disposed at two opposite sides of the transfer unit 21. The semiconductor processing apparatuses 100 may be grinding equipment, polishing equipment, measuring equipment, inspection equipment, laser equipment, cutting equipment, chamfering equipment, or the like, and the type of the semiconductor processing apparatus 100 is not limited and may be flexibly adjusted according to process requirements.

Each of the transfer units 21 includes a robotic arm 211 and a temporary storage area 212 (or buffer area) for temporarily storing various carriers. Preferably, the temporary storage area 212 is located within the transfer unit 21 and close to a side of the equipment front end module 1. The temporary storage area 212 is located far from the semiconductor processing apparatuses 100, so that the temporary storage area 212 will not obstruct semiconductor objects from entering or exiting the semiconductor processing apparatuses 100. The robotic arm 211 can be configured to pick and place the semiconductor objects, transport the semiconductor objects to the semiconductor processing apparatuses 100 or remove the semiconductor objects from the semiconductor processing apparatuses 100.

The storage and sorting apparatus 3 is disposed at another side of the equipment front end module 1. The storage and sorting apparatus 3 includes a plurality of storage slots 31, and the storage slots 31 are disposed at different heights to provide a multi-layer arrangement including a plurality of layers, and each layer of the multi-layer arrangement includes a plurality of storage slots 31. In this embodiment, the storage slots 31 are arranged in a polygonal configuration. As shown in FIG. 3, the storage slots 31 are arranged in an octagonal configuration. The interior of the storage and sorting apparatus 3 is hollow, so that a transport mechanism (not shown) may be disposed within the storage and sorting apparatus 3. The transport mechanism may include a robotic arm and the like, so as to transport (or convey) the semiconductor objects within the storage slot 31 to the equipment front end module 1, or transport (or convey) the semiconductor objects within the equipment front end module 1 into the storage slot 31.

The storage and sorting apparatus 3 is configured to store carriers, thereby increasing the storage capacity of the semiconductor objects that are to be processed (pending processing) and already processed (completed processing), and allowing appropriate classification. In this embodiment, the two storage and sorting apparatuses 3 are provided and respectively disposed at two opposite sides of the equipment front end module 1, such that the storage and sorting apparatus 3 located at two sides of the equipment front end module 1 are respectively aligned with the semiconductor processing apparatuses 100 located at two sides of the central transfer module 2. In this embodiment, the equipment front end module 1 and the storage and sorting apparatus 3 are arranged in a straight line, and a second transport path B (as shown in FIG. 3) is defined along the equipment front end module 1 and the storage and sorting apparatus 3. The second transport path B is located along the straight line, and the second transport path B may be perpendicular to the first transport path A, so that the equipment front end module 1, the central transfer module 2, and the storage and sorting apparatus 3 are configured to form a T-shaped arrangement. The semiconductor objects can move along the second transport path B and between the equipment front end module 1 and the storage and sorting apparatus 3, and the semiconductor objects can be rapidly transferred along the second transport path B. For example, the semiconductor objects can be transferred to the storage and sorting apparatus 3 along the second transport path B, or transferred from the storage and sorting apparatus 3 to the equipment front end module 1 along the second transport path B, so that the equipment front end module 1 and the storage and sorting apparatus 3 are arranged in an optimized layout, thereby reducing occupied space and enabling rapid transfer of the semiconductor objects.

The number of the storage and sorting apparatus 3 disposed at one or both sides of the equipment front end module 1 may be increased as needed. In another embodiment, a plurality of storage and sorting apparatuses 3 may also be disposed at one or both sides of the equipment front end module 1. For example, two, three, or four storage and sorting apparatuses 3 may be disposed at one or both sides of the equipment front end module 1, and two adjacent ones of the storage and sorting apparatuses 3 are internally interconnected or communicated to facilitate transport of the semiconductor objects. The storage and sorting apparatus 3 has a rectangular shape, allowing flexible assembly of the appropriate number of the storage and sorting apparatus 3 to increase storage capacity of the semiconductor objects that are to be processed and already processed. Preferably, the storage and sorting apparatuses 3 are respectively disposed at two sides of the equipment front end module 1, and the storage and sorting apparatuses 3 at the two sides of the equipment front end module 1 protrude beyond two opposite sides of the central transfer module 2, so that a space for accommodating the semiconductor processing apparatuses 100 can be formed between the storage and sorting apparatus 3 and the central transfer module 2, thereby achieving improved space utilization.

The beneficial effects of the present disclosure are that the semiconductor continuous processing integrated system includes an equipment front end module, a central transfer module, and at least one storage and sorting apparatus. The equipment front end module is provided with a load port, and the load port is configured to load and unload a plurality of carriers that are configured for carrying a plurality of semiconductor objects. The central transfer module is disposed at one side of the equipment front end module, the central transfer module and the load port are located at two opposite sides of the equipment front end module, the equipment front end module and the central transfer module are arranged in a straight line, a plurality of semiconductor processing apparatuses are disposed at two opposite sides of the central transfer module, a first transport path is defined along the equipment front end module and the central transfer module, the semiconductor objects are configured to move along the first transport path between the equipment front end module and the semiconductor processing apparatus, the central transfer module includes a plurality of transfer units arranged along the first transport path, each of the transfer units includes a robotic arm and a temporary storage area for temporarily storing the carriers, and the robotic arm is configured to pick and place the semiconductor objects. The at least one storage and sorting apparatus is disposed at another side of the equipment front end module, the equipment front end module and the storage and sorting apparatus are arranged in a straight line, a second transport path is defined along the equipment front end module and the storage and sorting apparatus, the semiconductor objects are configured to move along the second transport path between the equipment front end module and the storage and sorting apparatus, and the storage and sorting apparatus includes a plurality of storage slots arranged in a plurality of layers, and the storage slots of each of the layers are configured for storing the carriers.

The equipment front end module, the central transfer module, and the storage and sorting apparatus of the present disclosure can be arranged in an optimized configuration, such that the semiconductor objects can be transferred from the equipment front end module to the semiconductor processing apparatus, or from the semiconductor processing apparatus to the equipment front end module. Accordingly, bidirectional transport of the semiconductor objects is achieved, thereby forming an optimized object transfer path, which facilitates automated production and improves production efficiency.

Furthermore, the central transfer module of the present disclosure includes a plurality of transfer units. The transfer units are configured in a modular design, allowing flexible assembly and expansion in response to process requirements, thereby quickly realizing the construction of the central transfer module.

Additionally, the storage and sorting apparatus is disposed at a side of the equipment front end module for storing and sorting the carriers and the semiconductor objects, thereby increasing the storage capacity of “the semiconductor objects pending processing (or awaiting processing)” and “the semiconductor objects that have completed processing (or undergone processing),” and significantly improving production efficiency.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A semiconductor continuous processing integrated system, comprising:
an equipment front end module, wherein the equipment front end module is provided with a load port, and the load port is configured to load and unload a plurality of carriers that are configured for carrying a plurality of semiconductor objects;
a central transfer module, wherein the central transfer module is disposed at one side of the equipment front end module, the central transfer module and the load port are located at two opposite sides of the equipment front end module, the equipment front end module and the central transfer module are arranged in a straight line, a plurality of semiconductor processing apparatuses are disposed at two opposite sides of the central transfer module, a first transport path is defined along the equipment front end module and the central transfer module, the semiconductor objects are configured to move along the first transport path between the equipment front end module and the semiconductor processing apparatus, the central transfer module includes a plurality of transfer units arranged along the first transport path, each of the transfer units includes a robotic arm and a temporary storage area for temporarily storing the carriers, and the robotic arm is configured to pick and place the semiconductor objects; and
at least one storage and sorting apparatus, wherein the at least one storage and sorting apparatus is disposed at another side of the equipment front end module, the equipment front end module and the storage and sorting apparatus are arranged in a straight line, a second transport path is defined along the equipment front end module and the storage and sorting apparatus, the semiconductor objects are configured to move along the second transport path between the equipment front end module and the storage and sorting apparatus, and the storage and sorting apparatus includes a plurality of storage slots arranged in a plurality of layers, and the storage slots of each of the layers are configured for storing the carriers.

2. The semiconductor continuous processing integrated system according to claim 1, wherein the second transport path is perpendicular to the first transport path, and the equipment front end module, the central transfer module, and the storage and sorting apparatus are configured to form a T-shaped arrangement.

3. The semiconductor continuous processing integrated system according to claim 1, further comprising another storage and sorting apparatus, wherein the two storage and sorting apparatuses are respectively disposed at two opposite sides of the equipment front end module, so that the storage and sorting apparatuses located on both sides of the equipment front end module are respectively arranged in a row with the semiconductor processing apparatuses located on both sides of the central transfer module.

4. The semiconductor continuous processing integrated system according to claim 1, wherein the storage slots are arranged in a polygonal configuration.

5. The semiconductor continuous processing integrated system according to claim 1, wherein the at least one storage and sorting apparatus is disposed at one or both sides of the equipment front end module.

6. The semiconductor continuous processing integrated system according to claim 1, wherein the at least one storage and sorting apparatus is disposed at two sides of the equipment front end module, the storage and sorting apparatuses disposed at the two sides of the equipment front end module protrude beyond two opposite sides of the central transfer module, and the semiconductor processing apparatuses are accommodated between the storage and sorting apparatus and the central transfer module.

7. The semiconductor continuous processing integrated system according to claim 1, wherein the semiconductor processing apparatuses include grinding equipment, polishing equipment, measuring equipment, inspection equipment, laser equipment, cutting equipment, or chamfering equipment.

8. The semiconductor continuous processing integrated system according to claim 1, wherein the temporary storage area is located within the transfer unit and close to a side of the equipment front end module.

9. The semiconductor continuous processing integrated system according to claim 1, wherein the semiconductor continuous processing integrated system is configured to be applied to front-end processes of compound semiconductors.
